(19) United States
(12) Patent Application Publication
(10) Pub. No.: US 2022/0104397 A1
(43) Pub. Date: Mar. 31, 2022

(54) LIQUID COOLING RADIATOR BASED ON A WORKING MEDIUM CAPABLE OF LIQUID-LIQUID PHASE SEPARATION

(71) Applicant: China University of Petroleum (East China), Qingdao (CN)

(72) Inventors: Bin DING, Qingdao (CN); Yuan ZHANG, Qingdao (CN); Liang GONG, Qingdao (CN); Chuanyong ZHU, Qingdao (CN); Minghai XU, Qingdao (CN)

(21) Appl. No.: 17/186,320

(22) Filed: Feb. 26, 2021

(30) Foreign Application Priority Data
Sep. 29, 2020 (CN) 202011045866.6

(51) Int. Cl. H05K 7/20

(52) U.S. Cl. CPC H05K 7/20327; H05K 7/20309; H05K 7/20136

(57) ABSTRACT

A liquid cooling radiator based on a working medium capable of liquid-liquid phase separation includes a cooling fan, a micro liquid pump, a mixing pipe and a heat exchanger which are connected in sequence via a plastic tube. The liquid cooling radiator uses a solution capable of liquid-liquid phase separation at a lower critical separation temperature as a working medium, and is sealed after filling the solution into pipelines of the liquid cooling radiator. By replacing a working medium of the active CPU liquid cooling radiator, a heat dissipation performance in a limited space under a condition of a same pump power consumption, is greatly improved, a viscosity of the working medium in a heat-carrying state is reduced to decrease a flow resistance, which realizes both an enhancement of heat transfer and a reduction of flow resistance.

### CROSS REFERENCE TO RELATED APPLICATION

This application claims the priority of Chinese Patent Application No. 202011045866.6, entitled “LIQUID COOLING RADIATOR BASED ON A WORKING MEDIUM CAPABLE OF LIQUID-LIQUID PHASE SEPARATION” filed with the Chinese Patent Office on Sep. 29, 2020, which is incorporated herein by reference in its entirety.

### TECHNICAL FIELD

The present disclosure relates to the technical field of liquid cooling radiator, and in particular to a liquid cooling radiator based on a working medium capable of liquid-liquid phase separation.

### BACKGROUND ART

With the continuous development of microelectronic mechanical system, large-scale integrated circuit and high-power light-emitting diode, in the advanced engineering fields such as microelectronic technology, energy and power engineering, aerospace, chemical and biological engineering, and nuclear energy technology, increasing attentions are paid to the miniaturization and integration of the device. Subsequently, the heat flux of electronic devices increase rapidly, and the heat dissipation problem in hot spot areas (where the heat flux may reach 6 times of the surrounding areas) is more tricky. Taking a CPU or a GPU as an example, the CPU or GPU may automatically reduce the frequency at a high temperature, which has threats to the safety of other components in the main board and affects the performance of the CPU or GPU. In order to ensure safe and efficient operation of components such as CPU, cooling methods such as air cooling, water cooling, heat pipe cooling, thermoelectric cooling, and liquid nitrogen cooling have been developed, but the existing methods are challenging to achieve the multiple goals of heat transfer enhancement and flow resistance reduction.

Under the influence of the use environment and cost, the commercially CPU radiators are mainly the air cooling or the water cooling. The air cooling system uses air as a cooling medium, and usually includes a fan and some radiator fins, which are high in reliability but are poor in heat dissipation capability. By contrast, the heat dissipation capability increases by at least 4 times when the cooling medium is changed to water. Currently, water cooling system can be classified as active and passive, core components thereof are a heat exchanger, a circulation system, a water pump and a cooling working medium (mostly deionized water). Moreover, the cooling fan in the active water cooling system is the only difference from the passive system. The working process of the water cooling radiator is as follows: the water is pressurized by the pump and then quickly passes through the heat exchanger in contact with the CPU, material of the heat exchanger mostly employs pure copper with a high thermal conductivity, the cooling water takes away heat in a laminar flow pattern, and the working medium carrying heat dissipates heat by the cooling fan and then enters a next cycle. Since the cooling water is single-phase during heat transfer process in the laminar flow pattern and the increase in temperature has a small effect on physical parameters such as viscosity, optimizing channel structure and introducing structures such as micro-fins into a wall surface (to destroy a boundary layer, enhance a disturbance near walls, and increase heat transfer area) are common means for heat dissipation enhancement. However, these methods are likely to cause an increase in pressure drop, which limits the heat transfer effect in a limited space. As a result, it is difficult to further improve the performance of the existing water cooling radiator.

### SUMMARY

An object of some embodiments is to provide a liquid cooling radiator based on a working medium capable of liquid-liquid phase separation (partially miscible solution with a lower critical solution temperature), so as to solve the problems existing in the prior art. By replacing a working medium of an active liquid cooling radiator for CPU use, a heat dissipation performance in a limited space under a condition of a same pump power consumption, is greatly improved, a viscosity of the working medium in a liquid-liquid separation process is reduced to decrease a flow resistance to realize both an enhancement of heat transfer and a reduction of flow resistance.

In order to achieve the above object, the present disclosure provides the following solutions: a liquid cooling radiator based on a working medium capable of liquid-liquid phase separation, comprising a cooling fan, a micro liquid pump, a mixing pipe and a heat exchanger which are connected in sequence via a plastic tube, wherein the liquid cooling radiator employs a solution capable of liquid-liquid phase separation at a lower critical separation temperature as a working medium, and the liquid cooling radiator is sealed after filling the solution into pipelines of the liquid cooling radiator.

In some embodiments, the liquid cooling radiator is configured for heat dissipation of CPU or GPU, when the micro liquid pump is activated, the solution in the pipelines of the liquid cooling radiator flows into the heat exchanger through an inlet of the heat exchanger and is in a stable single-phase state, by convective heat transfer with internal extended surfaces of the heat exchanger, the solution is heated by the internal extended surfaces of the heat exchanger, and a temperature of the solution rapidly raises to the lower critical separation temperature so as to cause a liquid-liquid phase separation, the solution absorbs heat during the phase separation.

In some embodiments, the solution which has absorbed heat and taken place the liquid-liquid phase separation flows out of the heat exchanger through an outlet of the heat exchanger, and enters the cooling fan through the plastic tube which is able to withstand pressure.

In some embodiments, the solution in liquid-liquid phase separation state flows out of an outlet of the cooling fan, is pressurized by the micro liquid pump and flows into the mixing pipe with a length of 1.5 cm, the solution in liquid-liquid phase separation state is sufficiently miscible in the mixing pipe to reach the single-phase state before the liquid-liquid phase separation.

In some embodiments, the solution in the single-phase state flows out of the mixing pipe and is again introduced into the heat exchanger via the plastic tube for a next cycle.

In some embodiments, a temperature of the solution flowing into the heat exchanger is lower than the lower critical separation temperature of the solution.

In some embodiments, internal wall surfaces of the heat exchanger and the cooling fan are sprayed and coated with a nanometer silicon nitride.

In some embodiments, inner walls of the micro liquid pump and the plastic tube which is able to withstand pressure are sprayed and coated with polytetrafluoroethylene.

The present disclosure achieves the following beneficial technical effects compared with the prior art.

In the liquid cooling radiator based a working medium capable of liquid-liquid phase separation according to the present disclosure, in order to reduce the cost and improve the heat dissipation effect of the radiator on the basis of the current design, it is a key for solving the problem to introduce a new working medium, i.e., a solution capable of liquid-liquid phase separation, into the liquid cooling radiator. The convection heat transfer coefficient obtained by employing the solution is increased up to 2.5 times, in comparison with water. By replacing the working medium of the active CPU liquid cooling radiator, the heat dissipation performance in a limited space under the condition of the same pump power consumption, is greatly improved, the viscosity of the working medium in a heat-carrying state is reduced to decrease a flow resistance, which realizes both an enhancement of heat transfer and a reduction of flow resistance. The present disclosure satisfies the heat dissipation requirements from cluster computer to desktop computer, so that the temperature of the CPU is maintained at a low level all along to solve a problem of insufficient heat dissipation due to excessive heat generation of chips under the tendency of device miniaturization.

### BRIEF DESCRIPTION OF THE DRAWINGS

In order to more clearly illustrate the embodiments of the disclosure or the technical solutions in the prior art, the drawings required in the embodiments will be briefly described below, it is apparent that the drawings in the following description are only some embodiments of the disclosure, for those skilled in the art, other drawings can be obtained according to these drawings without inventive labors.

FIG. 1 is a diagram illustrating an arrangement of structures of a liquid cooling radiator.

List of reference numerals: 1 cooling fan, 2 micro liquid pump, 3 mixing pipe, 4 plastic tube, 5 heat exchanger.

### DETAILED DESCRIPTION OF THE EMBODIMENTS

The technical solutions in the embodiments of the present disclosure will be clearly and completely described below combining with the accompanying drawings in the embodiments of the present disclosure, and it is apparent that the embodiments described are only a part of the embodiments of the present disclosure, and not all of them. All other embodiments, which are obtained by a person skilled in the art based on the embodiments of the present disclosure without inventive labors, shall fall within the protection scope of the present disclosure.

An object of the present disclosure is to provide a liquid cooling radiator based on a working medium capable of liquid-liquid phase separation, so as to solve the problem existing in the prior art. By replacing a working medium of an active CPU liquid cooling radiator, the heat dissipation performance in a limited space under a condition of a same pump power consumption, is greatly improved and a viscosity of the working medium in a heat-carrying state is reduced to decrease a flow resistance, so as to realize both a enhancement of heat transfer and a reduction of flow resistance.

In order to make the above purposes, features and advantages of the present disclosure more comprehensible, the present disclosure is further and detailedly described combining with the accompanying drawings and specific embodiments thereof.

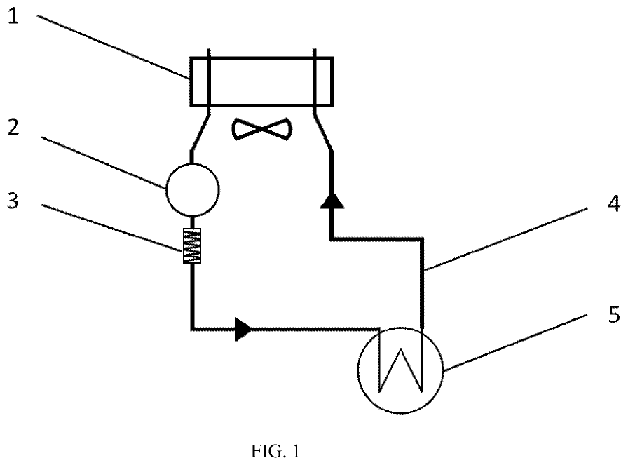

As shown in FIG. 1, it is provided a liquid cooling radiator based on a working medium capable of liquid-liquid phase separation in the present embodiment, which mainly changes a working medium of the CPU liquid cooling radiator. A mixing pipe 3 with a length of 1.5 cm is installed at an outlet of a micro liquid pump 2. The working flowchart of the modified liquid cooling radiator is shown in FIG. 1. A solution capable of liquid-liquid phase separation at a lower critical separation temperature (LCST) is employed as the working medium, and a mass fraction of a solute in the solution may be artificially adjusted according to a specific operation condition. The liquid cooling radiator is sealed after fully filled with the prepared solution. The liquid cooling radiator of the present disclosure includes a cooling fan 1, a micro liquid pump 2, a mixing pipe 3, a plastic tube 4 and a heat exchanger 5.

A working principle of the liquid cooling radiator based on a working medium capable of liquid-liquid phase separation in the present disclosure is as follows.

In step 1, a liquid pump is activated, the solution capable of liquid-liquid phase separation flows into the radiator through an inlet of the heat exchanger 5 which is in contact with the CPU. At this time, the solution is in a stable single-phase state. By convective heat transfer with an extended surface inside the heat exchanger 5, the solution is heated by wall surfaces of the heat exchanger 5, and thus a temperature of the solution rapidly raise to the lower critical separation temperature so as to induce a phase separation. A specific manner of the separation is the spinodal separation which does not have to overcome an energy barrier, and such separation process causes hydrogen bonds in the single-phase solution to break and recombine to form an immiscible solution, during which heat is absorbed.

In step 2, the solution which has absorbed heat and taken place liquid-liquid phase separation flows out of the heat exchanger 5 through an outlet of the heat exchanger 5, and enters the cooling fan 1 through the plastic tube 4 which can withstand pressure. The heat dissipation manner at this stage is the same as that of a fan end of the existing liquid cooling radiator.

In step 3, the solution in liquid-liquid phase separation state after cooling is not completely miscible. The solution flows out of an outlet of the cooling fan 1, and then is pressurized by the micro liquid pump 2. Subsequently, the solution flows through the mixing pipe 3 with a length of 1.5 cm, so that the solution may be sufficiently miscible again to reach a state before the phase separation, i.e. the uniform and stable single-phase.

In step 4, the stable single-phase solution flows out of the mixing pipe 3, and then is again introduced into the heat exchanger 5 via the plastic tube 4 for a next cycle.

During the cycle, the temperature of the solution flowing into the heat exchanger for the CPU is lower than the lower critical separation temperature of the solution. If the temperature is higher than the lower critical separation temperature, the solution itself is in a liquid-liquid phase separation state, and no phase separation occurs when the solution flows through the heat exchanger 5.

Components where heat transfer occurs are made of pure copper. The heat transfer areas of the components, for example internal wall surfaces of the CPU heat exchanger and the cooling fan 1, through which the solution capable of liquid-liquid phase separation flows are sprayed and coated with a nanometer silicon nitride. Fasteners are made of stainless steel. The inner walls of the micro liquid pump 2 and the plastic tube 4 which can withstand pressure are sprayed and coated with polytetrafluoroethylene.

Since during operation of a CPU liquid cooling radiator with water as a working medium, the water does not undergo phase transition, and thus the water is not an optimal working medium. The existing water cooling radiators mostly adopt the convection heat transfer via a single-phase fluid, then the flow resistance increases with a increase in the convection heat exchange coefficient of the radiator. In order to further improve the performance of the liquid cooling radiator and reduce the pump power consumption on the basis of the existing technology to satisfy a demand of apparatus miniaturization, a solution capable of liquid-liquid phase separation is employed as the working medium. A typical solution capable of liquid-liquid phase separation is an aqueous triethylamine solution with a mass fraction of 32.1%. Whatever solution capable of liquid-liquid phase separation is employed, the liquid-liquid phase separation occurs when a temperature of the solution is higher than the lower critical separation temperature, and meanwhile latent heat is absorbed during the separation process. Correspondingly, the solution is miscible (i.e., from two-phase state to single-phase state) when a temperature of the solution is lower than the lower critical separation temperature. It has been found that the convection heat transfer coefficient of the heat exchanger which uses the aqueous triethylamine solution as the working medium for heat transfer is increased up to 2.5 times, and the viscosity of such working medium is lower than water after the phase separation. With a tendency of device miniaturization, a liquid cooling radiator using the solution capable of liquid-liquid phase separation for CPU use can dissipate more heat under the condition of the same pump power consumption, and a smaller size of heat exchanger is required to dissipate the same heat. Thus, there are a wide application prospect and a great development potential for the present disclosure.

In the liquid cooling radiator based on the working medium capable of liquid-liquid phase separation according to the present disclosure, a solution capable of liquid-liquid phase separation is used as a working medium for heat transfer to substitute for traditional deionized water. Different kinds of solution capable of liquid-liquid phase separation for example an aqueous triethylamine solution are used according to different use environments, and the mass fraction of the solute can be changed to reach the optimal temperature for starting phase separation to adapt to different use environments. In order to ensure a safe and reliable operation of the liquid cooling radiator, all the inner walls of the heat exchanger in contact with the working medium are sprayed and coated with nanometer silicon nitride, and the inner walls of the micro liquid pump and the plastic tube which can withstand pressure are sprayed and coated with polytetrafluoroethylene, so as to reduce the flow resistance. In order to ensure that the cooled solution capable of liquid-liquid phase separation is sufficiently mixed, the pump is installed at an outlet of the cooling fan 1, out of which cooling liquid flows, and mixing pipe 3 with a length of 1.5 cm is connected in series between the plastic tube 4 and the outlet of the pump.

It should be noted that, for a person skilled in the art, the present disclosure is not limited to the details of the above exemplary embodiments, and the present disclosure can be implemented in other specific forms without departing from the spirit or basic features of the present disclosure. Therefore, the embodiments should be construed as exemplary and not restrictive from any point of view, and the scope of the present disclosure is defined by the appended claims rather than the foregoing description, and therefore it is intended that all changes falling within the meaning and range of equivalent elements of the claims are encompassed within the present disclosure, and that no reference signs in the claims should be construed as limiting claims.

The principle and the embodiments of the present disclosure are explained by using specific examples in the present disclosure, and the above description of the embodiments is only used to help understand the method and the core idea of the present disclosure. Moreover, it is apparent for a person skilled in the art to modify the specific embodiments and the application range according to the idea of the present disclosure. In conclusion, the contents of the description should not be construed as limitations on the disclosure.

What is claimed is:

1. A liquid cooling radiator based on a working medium capable of liquid-liquid phase separation, comprising a cooling fan, a micro liquid pump, a mixing pipe and a heat exchanger which are connected in sequence via a plastic tube, wherein the liquid cooling radiator employs a solution capable of liquid-liquid phase separation at a lower critical separation temperature as a working medium, and the liquid cooling radiator is sealed after filling the solution into pipelines of the liquid cooling radiator.

2. The liquid cooling radiator according to claim 1, wherein the liquid cooling radiator is configured for heat dissipation of CPU or GPU, when the micro liquid pump is activated, the solution in the pipelines of the liquid cooling radiator flows into the heat exchanger through an inlet of the heat exchanger and is in a stable single-phase state, by convective heat transfer with internal extended surfaces of the heat exchanger, the solution is heated by the internal extended surfaces of the heat exchanger, and a temperature of the solution rapidly raises to the lower critical separation temperature so as to cause a liquid-liquid phase separation, during which heat is absorbed.

3. The liquid cooling radiator according to claim 2, wherein the solution which has absorbed heat and taken place the liquid-liquid phase separation flows out of the heat exchanger through an outlet of the heat exchanger, and enters the cooling fan through the plastic tube which is able to withstand pressure.

4. The liquid cooling radiator according to claim 3, wherein the solution in liquid-liquid phase separation state flows out of an outlet of the cooling fan, is pressurized by the micro liquid pump and flows through the mixing pipe with a length of 1.5 cm, the solution in liquid-liquid phase separation state is sufficiently miscible in the mixing pipe to reach the single-phase state before the liquid-liquid phase separation.

5. The liquid cooling radiator according to claim 4, wherein the solution in the single-phase state flows out of the mixing pipe and is again introduced into the heat exchanger via the plastic tube for a next cycle.

6. The liquid cooling radiator according to claim 5, wherein a temperature of the solution flowing into the heat exchanger is lower than the lower critical separation temperature of the solution.

7. The liquid cooling radiator according to claim 1, wherein internal wall surfaces of the heat exchanger and the cooling fan are sprayed and coated with a nanometer silicon nitride.

8. The liquid cooling radiator according to claim 1, wherein inner walls of the micro liquid pump and the plastic tube which is able to withstand pressure are sprayed and coated with polytetrafluoroethylene.
